(19) United States
(12) Patent Application Publication
(10) Pub. No.: US 2026/0362917 A1
(43) Pub. Date: Nov. 12, 2026

(54) ARRAY BASE PLATE, DISPLAY PANEL, DISPLAY APPARATUS, AND METHOD FOR MANUFACTURING ARRAY BASE PLATE

(71) Applicant: Xiamen Tianma Display Technology Co., Ltd., Xiamen (CN)

(72) Inventors: Jiwei XIE, Xiamen (CN); Xinqi Ll, Xiamen (CN); Yana GAO, Xiamen (CN); Xingyao XHOU, Xiamen (CN)

(73) Assignee: Xiamen Tianma Display Technology Co., Ltd., Xiamen (CN)

(21) Appl. No.: 19/324,092

(22) Filed: Sep. 9, 2025

(30) Foreign Application Priority Data
May 8, 2025 (CN) 202510591600.8

(51) Int. Cl. H10K 59/131; H10K 59/12; H10K 59/121

(52) U.S. Cl. CPC H10K 59/131; H10K 59/1201; H10K 59/1216

(57) ABSTRACT

The present application discloses an array base plate, a display panel, a display apparatus, and a method for manufacturing the array base plate, the array base plate includes a substrate and a plurality of conductive layers, and the plurality of conductive layers are sequentially arranged at one side of the substrate; the plurality of conductive layers include a first conductive layer and a second conductive layer, the first conductive layer is disposed at one side of the substrate, and the first conductive layer includes a first conductive portion and a first electrode plate spaced apart from each other; the second conductive layer is disposed between the first conductive layer and the substrate, and the second conductive layer includes a second conductive portion and a second electrode plate spaced apart from each other.

### CROSS-REFERENCE TO RELATED APPLICATIONS

This application claims priority to Chinese Patent Application No. 202510591600.8, titled “ARRAY BASE PLATE, DISPLAY PANEL, DISPLAY APPARATUS, AND METHOD FOR MANUFACTURING ARRAY BASE PLATE” and filed on May 8, 2025, which is hereby incorporated by reference in its entirety.

### TECHNICAL FIELD

The present application relates to the field of display panels, and particularly to an array base plate, a display panel, a display apparatus, and a method for manufacturing the array base plate.

### BACKGROUND

Display panels using the technology of Organic Light Emitting Diode (OLED) have the advantages such as low power consumption, low production cost, self-luminescence, wide viewing angle, fast response, and the like. In the related art, a thin film transistor and a storage capacitor are adopted to cooperate together, so as to drive the light-emission unit to emit light. When all or part of the thin film transistors are polysilicon transistors, one electrode plate of the storage capacitor is arranged in the same layer as the gate of the polysilicon transistor, and the other electrode plate of the storage capacitor is formed by an independent conductive layer, thereby simplifying the process and reducing the cost. When all of the thin film transistors are oxide transistors, there is no need to provide polysilicon transistors, so two independent conductive layers need to be additionally provided to form a storage capacitor, resulting in an increase in the number of manufacturing steps and affecting the production efficiency.

### SUMMARY

Embodiments of the present application provide an array base plate, a display panel, a display apparatus, and a method for manufacturing the array base plate, which can simplify manufacturing steps and improve production efficiency.

In a first aspect, an array base plate is provided, the array base plate comprises a pixel circuit, the pixel circuit comprises at least one oxide transistor and at least one storage capacitor, and the array base plate comprises a substrate and a plurality of conductive layers, the plurality of conductive layers being sequentially arranged at a side of the substrate and comprising:
a first conductive layer, disposed at the side of the substrate, the first conductive layer comprising a first conductive portion and a first electrode plate that are spaced apart from each other;
a second conductive layer, disposed between the first conductive layer and the substrate, the second conductive layer comprising a second conductive portion and a second electrode plate that are spaced apart from each other,
wherein an orthographic projection of the first electrode plate on the substrate and an orthographic projection of the second electrode plate on the substrate at least partially overlap, the first electrode plate and the second electrode plate form at least part of the storage capacitor, the first conductive portion and the second conductive portion form two different functional portions of the oxide transistor respectively, and the functional portions of the oxide transistor comprise a first gate electrode, an active layer, and a first source-drain electrode.

In the first possible implementation, the functional portions of the oxide transistor further comprise a second gate electrode, the first gate electrode is located at a side of the active layer away from the substrate, the second gate electrode is located at a side of the active layer close to the substrate, an orthographic projection of the first gate electrode on the substrate partially overlaps an orthographic projection of the active layer on the substrate, and an orthographic projection of the second gate electrode on the substrate partially overlaps the orthographic projection of the active layer on the substrate.

In the first possible implementation, the functional portions of the oxide transistor further comprise a second source-drain electrode, the first source-drain electrode is disposed at a side of the second source-drain electrode away from the substrate, the first source-drain electrode is electrically connected to the second source-drain electrode, and the second source-drain electrode is electrically connected to the active layer.

In the first possible implementation, the functional portions of the oxide transistor further comprise a second gate electrode, the first gate electrode is located at a side of the active layer away from the substrate, the second gate electrode is located at a side of the active layer close to the substrate, an orthographic projection of the first gate electrode on the substrate partially overlaps an orthographic projection of the active layer on the substrate, an orthographic projection of the second gate electrode on the substrate partially overlaps an orthographic projection of the active layer on the substrate, the functional portions of the oxide transistor further comprise a second source-drain electrode, the first source-drain electrode is disposed at a side of the second source-drain electrode away from the substrate, the first source-drain electrode is electrically connected to the second source-drain electrode, and the second source-drain electrode is electrically connected to the active layer.

In the first possible implementation, the array base plate further comprises:
a third conductive layer, disposed at a side of the second conductive layer close to the substrate, the third conductive layer comprises a third electrode plate, the third electrode plate is electrically connected to the first electrode plate, an orthographic projection of the third electrode plate on the substrate and an orthographic projection of the second electrode plate on the substrate at least partially overlap, and the first electrode plate, the second electrode plate and the third electrode plate form at least part of the storage capacitor.

In the first possible implementation, the third conductive layer further comprises a third conductive portion, the third conductive portion is spaced apart from the third electrode plate, and the first conductive portion, the second conductive portion and the third conductive portion form three different functional portions of the oxide transistor respectively.

In the first possible implementation, the first conductive portion is the second source-drain electrode, the third conductive portion is the second gate electrode, and the second conductive portion is the active layer or the first gate electrode.

In the first possible implementation, the first conductive portion is the first source-drain electrode, the second conductive portion is the second source-drain electrode, and the third conductive portion is any one of the first gate electrode, the active layer and the second gate electrode.

In the first possible implementation, the first conductive portion is the first source-drain electrode, the third conductive portion is the second gate electrode, and the second conductive portion is the active layer or the first gate electrode.

In the first possible implementation, the array base plate further comprises:
a fourth conductive layer, disposed at a side of the third conductive layer close to the substrate, the fourth conductive layer comprises a fourth electrode plate, the fourth electrode plate is electrically connected to the second electrode plate, an orthographic projection of the fourth electrode plate on the substrate and an orthographic projection of the third electrode plate on the substrate at least partially overlap, the first electrode plate, the second electrode plate, the third electrode plate and the fourth electrode plate form at least part of the storage capacitor.

In the first possible implementation, the third conductive layer further comprises a third conductive portion, the third conductive portion is spaced apart from the third electrode plate, the fourth conductive layer further comprises a fourth conductive portion, the fourth conductive portion is spaced apart from the fourth electrode plate, the first conductive portion, the second conductive portion, the third conductive portion and the fourth conductive portion form four different functional portions of the oxide transistor respectively.

In the first possible implementation, the first conductive portion is the first source-drain electrode, the second conductive portion is the second source-drain electrode, the fourth conductive portion is the second gate electrode, and the third conductive portion is the active layer or the first gate electrode.

In the first possible implementation, the plurality of conductive layers comprise a fifth conductive layer, the fifth conductive layer comprises a first connection portion, the first conductive portion is connected to the first connection portion via a via, and the first connection portion is connected to the third conductive portion via the via.

In the first possible implementation, the fifth conductive layer and the second conductive layer are the same conductive layer, and the first connection portion, the second conductive portion and the second electrode plate are spaced apart from each other.

In the first possible implementation, the array base plate further comprises a plurality of insulation layers, the insulation layer is disposed between the adjacent conductive layers, the plurality of insulation layers comprise an organic insulation layer, and the organic insulation layer is disposed between the first conductive layer and the second conductive layer.

In the first possible implementation, the plurality of insulation layers comprise at least one inorganic insulation layer, and the at least one inorganic insulation layer is disposed between the second conductive layer and the third conductive layer.

In the first possible implementation, the array base plate further comprises a plurality of insulation layers, the insulation layer is disposed between the adjacent conductive layers, and the at least one insulation layer is disposed between the first electrode plate and the second electrode plate.

In the first possible implementation, the pixel circuit comprises a plurality of oxide transistors, the plurality of oxide transistors comprise a first transistor and a second transistor, and the active layer of the first transistor is connected to the active layer of the second transistor.

In a second aspect, there is provided a method for manufacturing an array base plate, comprising:
providing a substrate;
disposing a second conductive material layer at a side of the substrate, patterning the second conductive material layer to obtain a second conductive layer, the second conductive layer comprising a second conductive portion and a second electrode plate spaced apart from each other;
disposing a first insulation layer at a side of the second conductive layer away from the substrate;
disposing a first conductive material layer at a side of the first insulation layer away from the substrate, patterning the first conductive material layer to obtain a first conductive layer, the first conductive layer comprising a first conductive portion and a first electrode plate spaced apart from each other, an orthographic projection of the first electrode plate on the substrate and an orthographic projection of the second electrode plate on the substrate at least partially overlap, the first conductive portion and the second conductive portion form two different functional portions of an oxide transistor respectively, the functional portions of the oxide transistor comprise a first gate electrode, an active layer, and a first source-drain electrode.

In the first possible implementation, prior to the disposing a second conductive material layer at a side of the substrate, patterning the second conductive material layer to obtain a second conductive layer, the method further comprises:
disposing a third conductive material layer at the side of the substrate, patterning the third conductive material layer to obtain a third conductive layer, the third conductive layer comprising a third conductive portion and a third electrode plate spaced apart from each other;
disposing a second insulation layer at a side of the third conductive material layer away from the substrate;
the disposing a first conductive material layer at a side of the first insulation layer away from the substrate, patterning the first conductive material layer to obtain a first conductive layer, comprising:
   performing a drilling process on the first insulation layer and the second insulation layer to obtain a first via exposing a portion of the third electrode plate; and
   disposing the first conductive material layer at a side of the second insulation layer away from the substrate, patterning the first conductive material layer; the third electrode plate and the first electrode plate are connected through the first via, an orthographic projection of the third electrode plate on the substrate and the orthographic projection of the second electrode plate on the substrate at least partially overlap, the first conductive portion, the second conductive portion and the third conductive portion are configured to form the three different functional portions of the oxide transistor respectively,
   wherein the functional portions of the oxide transistor further comprise a second gate electrode and a second source-drain electrode, the first gate electrode is located at a side of the active layer away from the substrate, the second gate electrode is located at a side of the active layer close to the substrate, the first source-drain electrode is disposed at a side of the second source-drain electrode away from the substrate, the first source-drain electrode is electrically connected to the second source-drain electrode, and the second source-drain electrode is electrically connected to the active layer.

In the first possible implementation, prior to the disposing a third conductive material layer at the side of the substrate, patterning the third conductive material layer to obtain a third conductive layer, the method further comprises:
disposing a fourth conductive material layer at the side of the substrate, patterning the fourth conductive material layer to obtain a fourth conductive layer, the fourth conductive layer comprising a fourth conductive portion and a fourth electrode plate spaced apart from each other;
disposing a third insulation layer at a side of the fourth conductive material layer away from the substrate;

the disposing a second conductive material layer at a side of the substrate, patterning the second conductive material layer to obtain a second conductive layer, comprising:
performing the drilling process on the second insulation layer and the third insulation layer to obtain a second via exposing a portion of the fourth electrode plate;
disposing the second conductive material layer at the side of the second insulation layer away from the substrate, patterning the second conductive material layer, the fourth electrode plate and the second electrode plate are connected through the second via, an orthographic projection of the fourth electrode plate on the substrate and the orthographic projection of the third electrode plate on the substrate at least partially overlap, and the first conductive portion, the second conductive portion, the third conductive portion and the fourth conductive portion are configured to form the four different functional portions of the oxide transistor respectively.

In a third aspect, a display panel is provided, and the display panel comprises the above-mentioned array base plate, or the array base plate manufactured by the above-mentioned method for manufacturing the array base plate.

In a fourth aspect, a display apparatus is provided, and the display apparatus comprises the above-mentioned display panel.

In the present application, the first conductive layer includes the first conductive portion and the first electrode plate spaced apart from each other, the second conductive layer includes the second conductive portion and the second electrode plate spaced apart from each other, the first electrode plate and the second electrode plate form at least part of the storage capacitor, and the first conductive portion and the second conductive portion from two different functional portions of the oxide transistor respectively, so that when two different functional portions of the oxide transistor are manufactured, the first electrode plate and the second electrode plate of the storage capacitor are manufactured simultaneously, and the step of separately manufacturing the conductive layers for forming the electrode plates of the storage capacitor is omitted, the mask plate of the electrode plates of the storage capacitor formed by patterning is omitted, thereby improving the manufacturing efficiency of the array base plate.

### BRIEF DESCRIPTION OF THE DRAWINGS

In order to illustrate technical solutions of embodiments of the present application more clearly, the drawings to be used in the embodiments of the present application will be described briefly below, apparently, the drawings described below are merely some embodiments of the present application, and other drawings may be obtained by those skilled in the art according to the drawings without any inventive effort.

FIG. 1 is a partial cross-sectional structural schematic diagram of an array base plate according to an embodiment of the present application;

FIG. 2 is a partial cross-sectional structural schematic diagram of an array base plate according to an embodiment of the present application;

FIG. 3 is a partial cross-sectional structural schematic diagram of an array base plate according to an embodiment of the present application;

FIG. 4 is a partial cross-sectional structural schematic diagram of an array base plate according to an embodiment of the present application;

FIG. 5 is a partial cross-sectional structural schematic diagram of an array base plate according to an embodiment of the present application;

FIG. 6 is a partial cross-sectional structural schematic diagram of an array base plate according to an embodiment of the present application;

FIG. 7 is a partial cross-sectional structural schematic diagram of an array base plate according to an embodiment of the present application;

FIG. 8 is a partial cross-sectional structural schematic diagram of an array base plate according to an embodiment of the present application;

FIG. 9 is a partial cross-sectional structural schematic diagram of an array base plate according to an embodiment of the present application;

FIG. 10 is a partial cross-sectional structural schematic diagram of an array base plate according to an embodiment of the present application;

FIG. 11 is a partial cross-sectional structural schematic diagram of an array base plate according to an embodiment of the present application;

FIG. 12 is a partial cross-sectional structural schematic diagram of an array base plate according to an embodiment of the present application;

FIG. 13 is a partial cross-sectional structural schematic diagram of an array base plate according to an embodiment of the present application;

FIG. 14 is a partial cross-sectional structural schematic diagram of an array base plate according to an embodiment of the present application;

FIG. 15 is a partial cross-sectional structural schematic diagram of an array base plate according to an embodiment of the present application;

FIG. 16 is a partial cross-sectional structural schematic diagram of an array base plate according to an embodiment of the present application;

FIG. 17 is a partial cross-sectional structural schematic diagram of an array base plate according to an embodiment of the present application;

FIG. 18 is a partial cross-sectional structural schematic diagram of an array base plate according to an embodiment of the present application;

FIG. 19 is a partial cross-sectional structural schematic diagram of an array base plate according to an embodiment of the present application;

FIG. 20 is a flowchart of a method for manufacturing the array base plate according to an embodiment of the present application;

FIG. 21 is a cross-sectional structural schematic diagram of a display panel according to an embodiment of the present application; and

FIG. 22 is a planar structural schematic diagram of a display apparatus according to an embodiment of the present application.

### REFERENCE NUMERALS

10, oxide transistor; 11, first gate electrode; 12, active layer; 13, first source-drain electrode; 14, second gate electrode; 15, second source-drain electrode; 20, storage capacitor;

1, substrate; 2, first conductive layer; 21, first conductive portion; 22, first electrode plate; 3, second conductive layer; 31, second conductive portion; 32, second electrode plate; 4, third conductive layer; 41, third conductive portion; 42, third electrode plate; 5, fourth conductive layer; 51, fourth conductive portion; 52, fourth electrode plate; 6, fifth conductive layer; 61, first connection portion; 7a, organic insulation layer; 7b, inorganic insulation layer; 81, second connection portion; 82, third connection portion;

200, display panel; 201, housing; 301, light-emission unit; 302, encapsulation layer; 303, touch layer; 304, adhesive layer; 305, cover plate;

X, first direction.

### DETAILED DESCRIPTION

Features and exemplary embodiments of various aspects of the present application will be described in detail below. In the following detailed description, numerous specific details are set forth in order to provide a thorough understanding of the present application. However, it will be apparent for those skilled in the art that, the present application may be implemented without some of these specific details. The following description of the embodiments is merely intended to provide a better understanding of the present application by illustrating examples of the present application.

It should be noted that, the embodiments and features in the embodiments of the present application may be combined with each other as long as there is no conflict. Hereinafter, embodiments will be described in detail with reference to the drawings.

In a first aspect, the embodiments of the present application provide an array base plate.

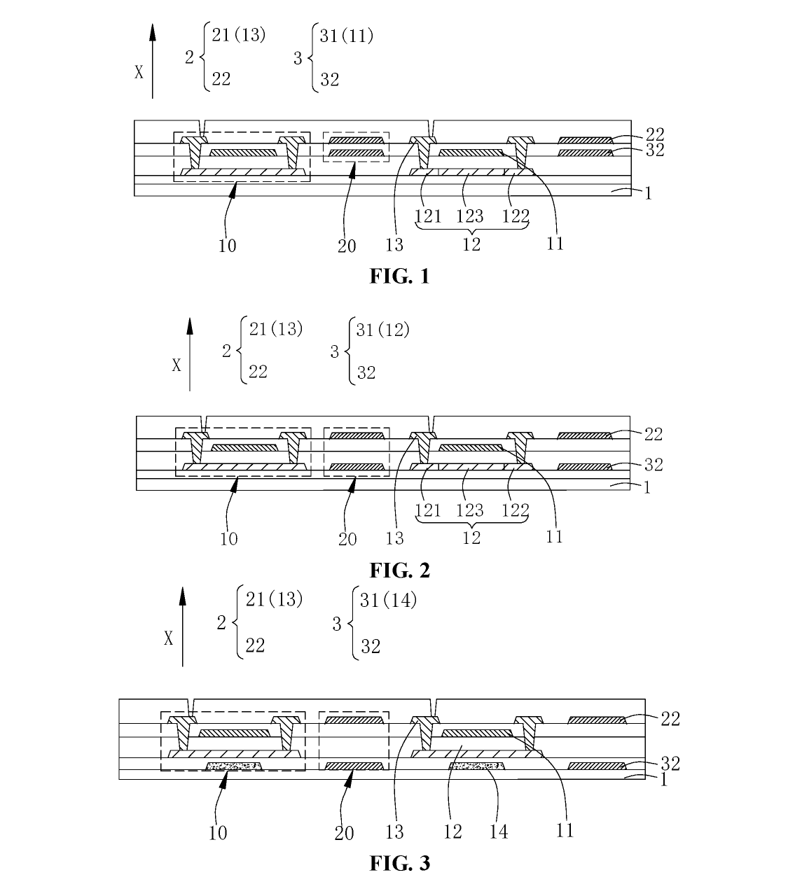

Referring to FIG. 1, the array base plate comprises a pixel circuit, the pixel circuit includes at least one oxide transistor 10 and at least one storage capacitor 20, the array base plate includes a substrate 1 and a plurality of conductive layers, and the plurality of conductive layers are sequentially arranged at the side of the substrate 1; the plurality of conductive layers include a first conductive layer 2 and a second conductive layer 3, the first conductive layer 2 is disposed at the side of the substrate 1, and the first conductive layer 2 includes a first conductive portion 21 and a first electrode plate 22 spaced apart from each other; the second conductive layer 3 is disposed between the first conductive layer 2 and the substrate 1, and the second conductive layer 3 includes a second conductive portion 31 and a second electrode plate 32 spaced apart from each other; and an orthographic projection of the first electrode plate 22 on the substrate 1 at least partially overlaps an orthographic projection of the second electrode plate 32 on the substrate 1, the first electrode plate 22 and the second electrode plate 32 form at least part of the storage capacitor 20, the first conductive portion 21 and the second conductive portion 31 form two different functional portions of the oxide transistor 10 respectively, and the functional portions of the oxide transistor 10 include a first gate electrode 11, an active layer 12, and a first source-drain electrode 13.

The array base plate provided in the embodiments of the present application can be configured to manufacture a display panel, and the display panel may be a display panel based on the technology of Organic Light Emitting Diode (OLED).

One or more pixel circuits are provided in the array base plate, and the pixel circuit can provide an electrical signal to the light-emission unit of the display panel, so that the electrical signal of the pixel circuit is controlled, so as to control the light-emission duration or whether the light-emission unit emits light. A plurality of thin film transistors are provided in the pixel circuit for controlling any light-emission unit, and the pixel circuit may be any one of a 2T1C circuit, a 3T1C circuit, a 3T2C circuit, a 7T1C circuit, or a 7T2C circuit. In the present application, "2T1C circuit" refers that the pixel circuit for controlling any light-emission unit includes two thin film transistors (T) and one capacitor (C), and other "7T1C circuit", "7T2C circuit", and "9T1C circuit", etc. are analogous.

Among the plurality of thin film transistors of the pixel circuit, any thin film transistor may be an oxide transistor 10 or a low temperature polysilicon (LTPS) transistor. A metal oxide semiconductor material is used in the oxide transistor 10 as the active layer 12, and the metal oxide semiconductor material may be indium gallium zinc oxide (IGZO), zinc tin oxide (ZTO), or indium gallium tin zinc oxide (IGTZO). The polysilicon is used in polysilicon transistors as the active layer. During the manufacturing of a polysilicon transistor, amorphous silicon is converted into polysilicon by performing laser annealing treatment on amorphous silicon, so as to improve electron mobility. The array base plate provided in the present application includes at least one oxide transistor 10. Optionally, the transistors in the array base plate provided in the present application each are an oxide transistor 10.

The oxide transistor 10 at least includes an active layer 12, a first gate electrode 11, and a first source-drain electrode 13; the active layer 12 includes a channel region 123, and a source region 121 and a drain region 122 disposed at two sides of the channel region 123 respectively, and the channel region 123 and the first gate electrode 11 are disposed opposite to each other and spaced apart from each other; and the first source-drain electrode 13 includes a source electrode and a drain electrode spaced apart from each other, the source electrode is connected to the source region 121 through a via, and the drain electrode is connected to the drain region 122 through a via. The oxide transistor 10 may be a single-gate transistor having one gate electrode or a double-gate transistor having two gate electrodes. The oxide transistor 10 may further be a top-gate structure in which the gate electrode is located at the side of the active layer 12 away from the substrate 1, or may be a bottom-gate structure in which the gate electrode is located at the side of the active layer 12 close to the substrate 1. The first gate electrode 11 may be located at the side of the active layer 12 away from the substrate 1, or may be located at the side of the active layer 12 close to the substrate 1. When the oxide transistor 10 has multiple layers of source-drain electrodes, the first source-drain electrode 13 is any one of the multiple layers of source-drain electrodes.

The substrate 1 may provide support for a plurality of conductive layers. The substrate 1 may be a rigid material or a flexible material. The rigid material includes, but is not limited to, glass. The flexible material includes, but is not limited to, polyimide (PI), ultra-thin glass (UTG), or polyethylene terephthalate (PET).

The plurality of conductive layers are sequentially arranged on the substrate 1, and an insulation layer is disposed between the adjacent conductive layers to avoid unnecessary electrical connection between the adjacent conductive layers. For two of the plurality of conductive layers, a via penetrating the insulation layer between two conductive layers is formed, and two conductive layers are electrically connected through the via.

In the plurality of conductive layers, any two conductive layers may be made of the same conductive material or different conductive materials. Different structures of the same conductive layer can be manufactured in the same process. For example, a first conductive material layer is disposed at the side of the substrate 1, and the first conductive material layer is patterned to obtain the first conductive portion 21 and the first electrode plate 22. Different conductive layers can be manufactured in different processes. For example, a second conductive layer 3 is formed at the side of the substrate 1, an insulation layer is formed at the side of the second conductive layer 3 away from the substrate, and a first conductive layer 2 is formed at the side of the insulation layer away from the substrate. Any one of the conductive layers may be manufactured by a single conductive material. For example, the metal layer formed with the active layer 12 is manufactured by using IGZO, and the metal layer formed with the first gate electrode 11 is manufactured by using molybdenum (Mo). Any one of the conductive layers may be manufactured by using multiple layers of conductive materials. For example, the metal layer formed with the first gate electrode 11 may be made of titanium (Ti)/aluminum (Al)/Ti stacked in sequence.

An orthographic projection of the first electrode plate 22 on the substrate 1 at least partially overlaps an orthographic projection of the second electrode plate 32 on the substrate 1, so that the first electrode plate 22 and the second electrode plate 32 are arranged oppositely and spaced apart from each other to form a storage capacitor. The facing area of the first electrode plate 22 and the second electrode plate 32 affects the capacitance value of the storage capacitor, and the facing area size of the first electrode plate 22 and the second electrode plate 32 can be adjusted according to the required capacitance value. Optionally, the orthographic projection of the first electrode plate 22 on the substrate 1 coincides with the orthographic projection of the second electrode plate 32 on the substrate 1. Unless otherwise specified, each of the orthographic projections in the present application is a projection along a first direction X, and the first direction X may be a thickness direction of the array base plate, or a direction perpendicular to the plane where the substrate 1 is located.

The first conductive portion 21 and the second conductive portion 31 form two different functional portions of the oxide transistor 10 respectively. Exemplarily, as shown in FIG. 1, the first conductive portion 21 forms the first source-drain electrode 13, the second conductive portion 31 forms the first gate electrode 11, the first electrode plate 22 and the first source-drain electrode 13 are manufactured in the same layer, and the second electrode plate 32 and the first gate electrode 11 are manufactured in the same layer. Exemplarily, as shown in FIG. 2, the first conductive portion 21 forms the first source-drain electrode 13, the second conductive portion 31 forms the active layer 12, the first electrode plate 22 and the first source-drain electrode 13 are manufactured in the same layer, and the second electrode plate 32 and the active layer 12 are manufactured in the same layer.

In the embodiments of the present application, the first conductive layer 2 includes a first conductive portion 21 and a first electrode plate 22 spaced apart from each other, the second conductive layer 3 includes a second conductive portion 31 and a second electrode plate 32 spaced apart from each other, the first electrode plate 22 and the second electrode plate 32 form at least part of the storage capacitor 20, and the first conductive portion 21 and the second conductive portion 31 form two different functional portions of the oxide transistor 10 respectively, so that during the manufacturing of two different functional portions of the oxide transistor 10, the first electrode plate 22 and the second electrode plate 32 forming the storage capacitor 20 are manufactured together, so as to omit the step of separately preparing the conductive layers for forming the electrode plates of the storage capacitor 20 and the mask plate for patterning the electrode plates forming the storage capacitor 20, thereby improving the manufacturing efficiency of the array base plate.

Referring to FIG. 3, in some embodiments, the functional portions of the oxide transistor 10 further include a second gate electrode 14; the first gate electrode 11 is located at the side of the active layer 12 away from the substrate 1, and the second gate electrode 14 is located at the side of the active layer 12 close to the substrate 1; the orthographic projection of the first gate electrode 11 on the substrate 1 partially overlaps the orthographic projection of the active layer 12 on the substrate 1, and the orthographic projection of the second gate electrode 14 on the substrate 1 partially overlaps the orthographic projection of the active layer 12 on the substrate 1.

The first gate electrode 11 and the second gate electrode 14 each are spaced apart from the channel region 123 of the active layer 12, thereby enhancing the current driving capability of the oxide transistor 10.

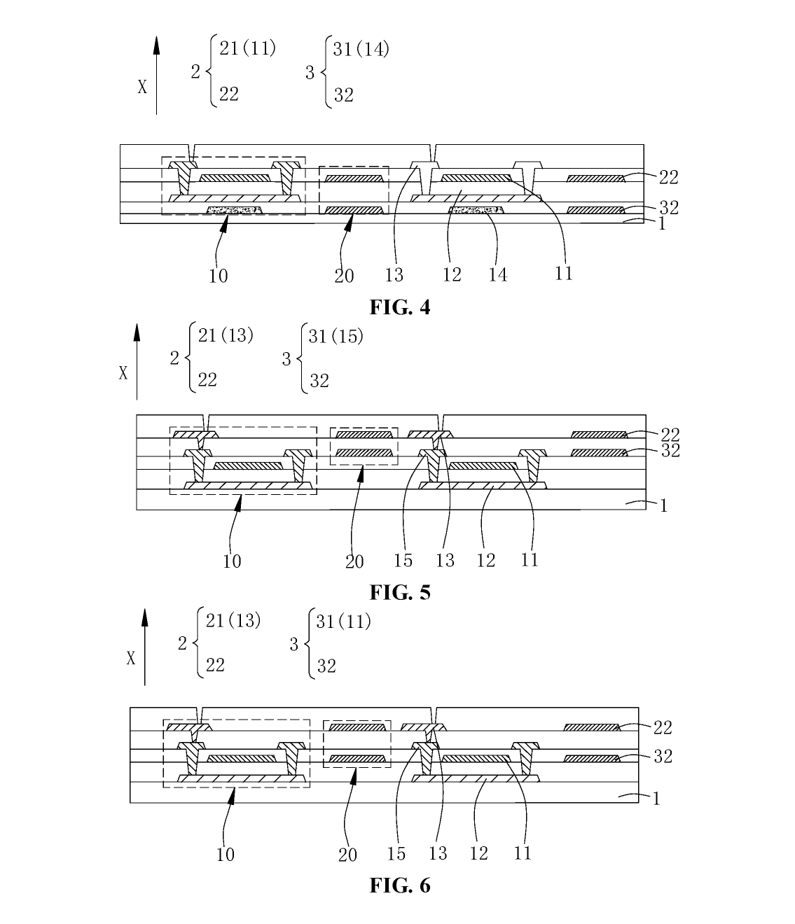

The first conductive portion 21 serves as one of the first gate electrode 11, the active layer 12, the first source-drain electrode 13, and the second gate electrode 14, and the second conductive portion 31 serves as one of the first gate electrode 11, the active layer 12, the first source-drain electrode 13, and the second gate electrode 14. Exemplarily, the first conductive portion 21 serves as the first source-drain electrode 13, the second conductive portion 31 serves as the second gate electrode 14, the first electrode plate 22 and the first source-drain electrode 13 are manufactured in the same layer, and the second electrode plate 32 and the second gate electrode 14 are manufactured in the same layer. Exemplarily, referring to FIG. 4, the first conductive portion 21 serves as the first gate electrode 11, the second conductive portion 31 serves as the second gate electrode 14, the first electrode plate 22 and the first gate electrode 11 are manufactured in the same layer, and the second electrode plate 32 and the second gate electrode 14 are manufactured in the same layer.

Referring to FIG. 5, in some embodiments, the functional portions of the oxide transistor 10 further include a second source-drain electrode 15, the first source-drain electrode 13 is disposed at the side of the second source-drain electrode 15 away from the substrate 1, the first source-drain electrode 13 is electrically connected to the second source-drain electrode 15, and the second source-drain electrode 15 is electrically connected to the active layer 12.

The second source-drain electrode 15 includes a source electrode and a drain electrode spaced apart from each other; the first source-drain electrode 13 may be electrically connected to one of the source electrode and the drain electrode, and the first source-drain electrode 13 is also connected to the driving electrode of the light-emission unit through a via to provide an electrical signal to the driving electrode. Optionally, the driving electrode is an anode or a cathode.

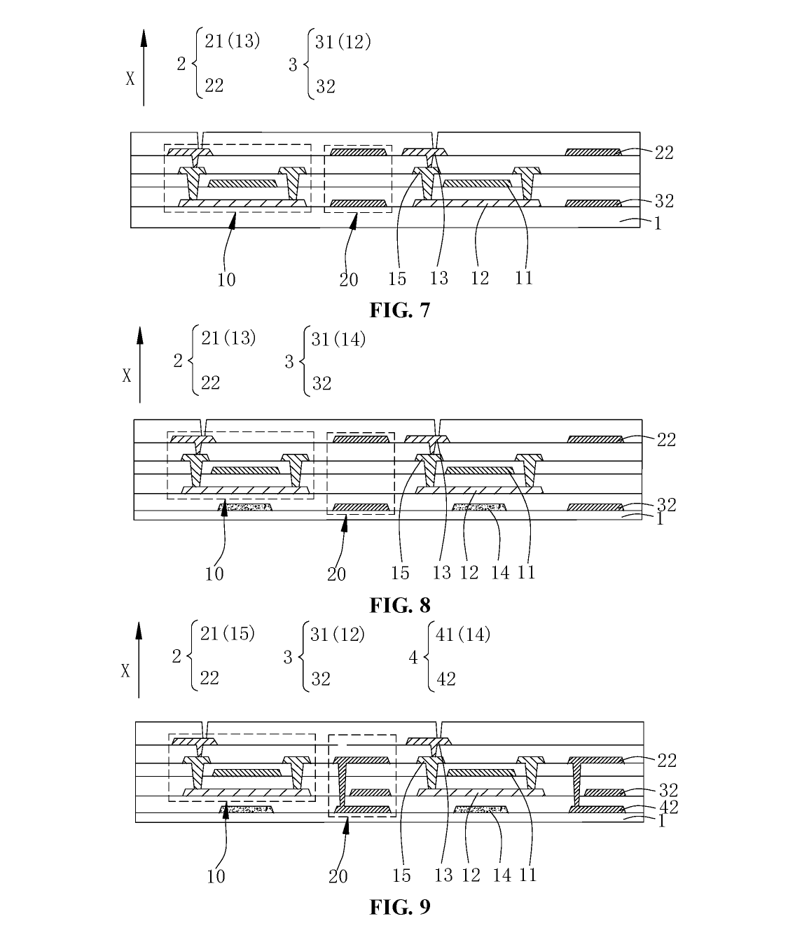

The first conductive portion 21 serves as one of the first gate electrode 11, the active layer 12, the first source-drain electrode 13, and the second source-drain electrode 15, and the second conductive portion 31 serves as one of the first gate electrode 11, the active layer 12, the first source-drain electrode 13, and the second source-drain electrode 15. Exemplarily, the first conductive portion 21 serves as the first source-drain electrode 13, the second conductive portion 31 serves as the second source-drain electrode 15, the first electrode plate 22 and the first source-drain electrode 13 are manufactured in the same layer, and the second electrode plate 32 and the second source-drain electrode 15 are manufactured in the same layer. Exemplarily, referring to FIG. 6, the first conductive portion 21 serves as the first source-drain electrode 13, the second conductive portion 31 serves as the first gate electrode 11, the first electrode plate 22 and the first source-drain electrode 13 are manufactured in the same layer, and the second electrode plate 32 and the first gate electrode 11 are manufactured in the same layer. Exemplarily, referring to FIG. 7, the first conductive portion 21 serves as the first source-drain electrode 13, the second conductive portion 31 serves as the active layer 12, the first electrode plate 22 and the first source-drain electrode 13 are manufactured in the same layer, and the second electrode plate 32 and the active layer 12 are manufactured in the same layer.

Referring to FIG. 8, in some embodiments, the functional portions of the oxide transistor 10 further include a first gate electrode 11 and a second gate electrode 14, the first gate electrode 11 is located at the side of the active layer 12 away from the substrate 1, the second gate electrode 14 is located at the side of the active layer 12 close to the substrate 1; the orthographic projection of the first gate electrode 11 on the substrate 1 partially overlaps the orthographic projection of the active layer 12 on the substrate 1, and the orthographic projection of the second gate electrode 14 on the substrate 1 partially overlaps the orthographic projection of the active layer 12 on the substrate 1; and the functional portions of the oxide transistor 10 further include a first source-drain electrode 13 and a second source-drain electrode 15, the first source-drain electrode 13 is disposed on the side of the second source-drain electrode 15 away from the substrate 1, the first source-drain electrode 13 is electrically connected to the second source-drain electrode 15, and the second source-drain electrode 15 is electrically connected to the active layer 12.

When manufacturing the oxide transistor 10, the conductive layer for forming the second gate electrode 14, the conductive layer for forming the active layer 12, the conductive layer for forming the first gate electrode 11, the conductive layer for forming the second source-drain electrode 15, and the conductive layer for forming the first source-drain electrode 13 may be sequentially manufactured. When the pixel circuit includes multiple oxide transistors 10, the conductive material layer is patterned to simultaneously manufacture the same functional portion of the multiple oxide transistors 10.

The first conductive portion 21 serves as one of the first gate electrode 11, the active layer 12, the second gate electrode 14, the first source-drain electrode 13, and the second source-drain electrode 15, and the second conductive portion 31 serves as one of the first gate electrode 11, the active layer 12, the second gate electrode 14, the first source-drain electrode 13, and the second source-drain electrode 15. Exemplarily, the first conductive portion 21 serves as the first source-drain electrode 13, the second conductive portion 31 serves as the second gate electrode 14, the first electrode plate 22 and the first source-drain electrode 13 are manufactured in the same layer, and the second electrode plate 32 and the second gate electrode 14 are manufactured in the same layer.

Referring to FIG. 9, in some embodiments, the array base plate further includes a third conductive layer 4; the third conductive layer 4 is disposed at the side of the second conductive layer 3 close to the substrate 1; the third conductive layer 4 includes a third electrode plate 42, the third electrode plate 42 is electrically connected to the first electrode plate 22; and the orthographic projection of the third electrode plate 42 on the substrate 1 at least partially overlaps the orthographic projection of the second electrode plate 32 on the substrate 1, and the first electrode plate 22, the second electrode plate 32, and the third electrode plate 42 form at least part of the storage capacitor 20.

During the manufacturing of the oxide transistor 10, the third conductive layer 4 can be manufactured first, then the second conductive layer 3 can be manufactured, and then the first conductive layer 2 can be manufactured. The orthographic projection of the third electrode plate 42 on the substrate 1 at least partially overlaps the orthographic projection of the second electrode plate 32 on the substrate 1, so that a capacitor is formed between the first electrode plate 22 and the second electrode plate 32, and a capacitor is formed between the second electrode plate 32 and the third electrode plate 42. The capacitance value of a capacitor is positively correlated with the area of electrode plates, and negatively correlated with the distance between electrode plates. The first electrode plate 22, the second electrode plate 32, and the third electrode plate 42 are disposed to form the storage capacitor 20, so that the capacitance value of the storage capacitor 20 can be increased, and the area of a single electrode plate can be reduced. When the array base plate is applied to the display panel, the pixel circuit correspondingly controls one light-emission unit. By reducing the area of a single electrode plate, the area of the entire pixel circuit can be reduced, and the distance between adjacent light-emission units can be reduced.

The third electrode plate 42 is electrically connected to the first electrode plate 22, so that the third electrode plate 42 and the first electrode plate 22 have the same potential, and can be connected to the pixel circuit through either the first electrode plate 22 or the third electrode plate 42, thereby simplifying the design of the pixel circuit.

The second electrode plate 32 is located between the first electrode plate 22 and the third electrode plate 42, and the via connecting the first electrode plate 22 and the third electrode plate 42 is located at one side of the second electrode plate 32 and is spaced apart from the second electrode plate 32. Optionally, the orthographic projection of the first electrode plate 22 on the substrate 1 coincides with the orthographic projection of the third electrode plate 42 on the substrate 1, and the orthographic projection of the second electrode plate 32 on the substrate 1 is located within the orthographic projection of the first electrode plate 22 on the substrate 1.

In some embodiments, the third conductive layer 4 further includes a third conductive portion 41, the third conductive portion 41 is spaced apart from the third electrode plate 42, and the first conductive portion 21, the second conductive portion 31, and the third conductive portion 41 serve as three different functional portions of the oxide transistor 10 respectively.

The third conductive portion 41 is one of the first gate electrode 11, the second gate electrode 14, the active layer 12, the first source-drain electrode 13, and the second source-drain electrode 15 of the oxide transistor 10. When the conductive material is patterned to obtain the third conductive portion 41, the third electrode plate 42 is also manufactured, thereby simplifying the manufacturing step.

In some embodiments, the first conductive portion 21 is the second source-drain electrode 15, the third conductive portion 41 is the second gate electrode 14, and the second conductive portion 31 is the active layer 12 or the first gate electrode 11.

Exemplarily, the first conductive portion 21 serves as the second source-drain electrode 15, and the first electrode plate 22 and the second source-drain electrode 15 are manufactured in the same layer; the second conductive portion 31 serves as the active layer 12, and the second electrode plate 32 and the active layer 12 are manufactured in the same layer; and the third conductive portion 41 serves as the second gate electrode 14, and the third electrode plate 42 and the second gate electrode 14 are manufactured in the same layer.

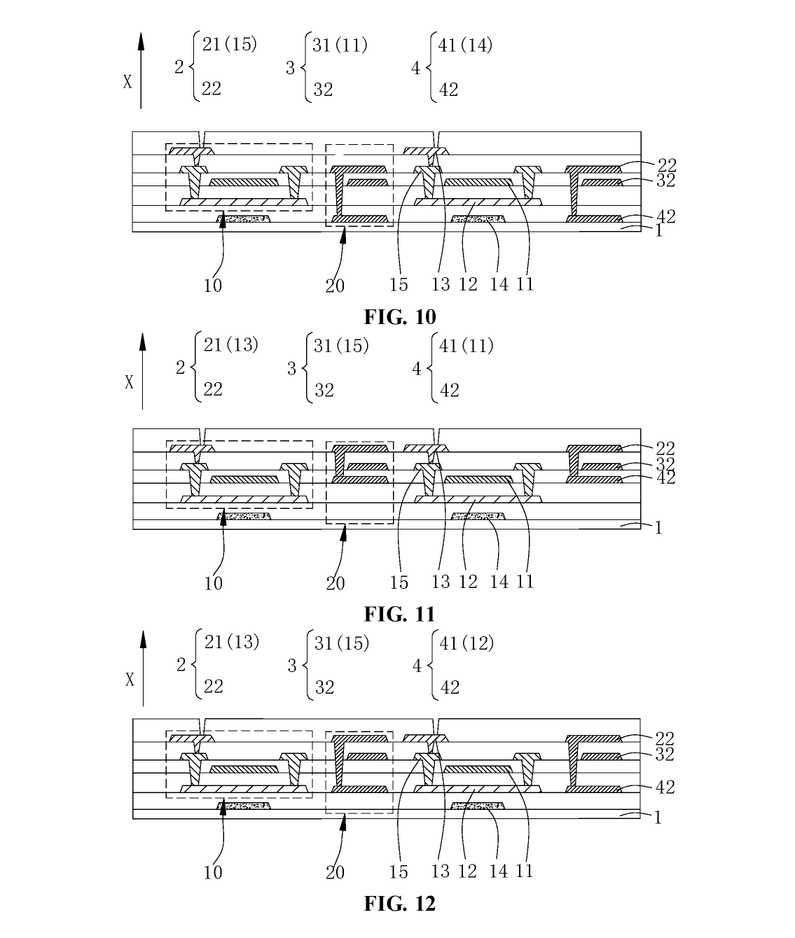

Exemplarily, referring to FIG. 10, the first conductive portion 21 serves as the second source-drain electrode 15, and the first electrode plate 22 and the second source-drain electrode 15 are manufactured in the same layer; the second conductive portion 31 serves as the first gate electrode 11, and the second electrode plate 32 and the first gate electrode 11 are manufactured in the same layer; and the third conductive portion 41 serves as the second gate electrode 14, and the third electrode plate 42 and the second gate electrode 14 are manufactured in the same layer.

Referring to FIG. 11, in some embodiments, the first conductive portion 21 serves as the first source-drain electrode 13, the second conductive portion 31 serves as the second source-drain electrode 15, and the third conductive portion 41 serves as any one of the first gate electrode 11, the active layer 12, and the second gate electrode 14.

Exemplarily, the first conductive portion 21 serves as the first source-drain electrode 13, and the first electrode plate 22 and the first source-drain electrode 13 are manufactured in the same layer; the second conductive portion 31 serves as the second source-drain electrode 15, and the second electrode plate 32 and the second source-drain electrode 15 are manufactured in the same layer; and the third conductive portion 41 serves as the first gate electrode 11, and the third electrode plate 42 and the first gate electrode 11 are manufactured in the same layer.

Exemplarily, referring to FIG. 12, the first conductive portion 21 serves as the first source-drain electrode 13, and the first electrode plate 22 and the first source-drain electrode 13 are manufactured in the same layer; the second conductive portion 31 serves as the second source-drain electrode 15, and the second electrode plate 32 and the second source-drain electrode 15 are manufactured in the same layer; and the third conductive portion 41 serves as the active layer 12, and the third electrode plate 42 and the active layer 12 are manufactured in the same layer.

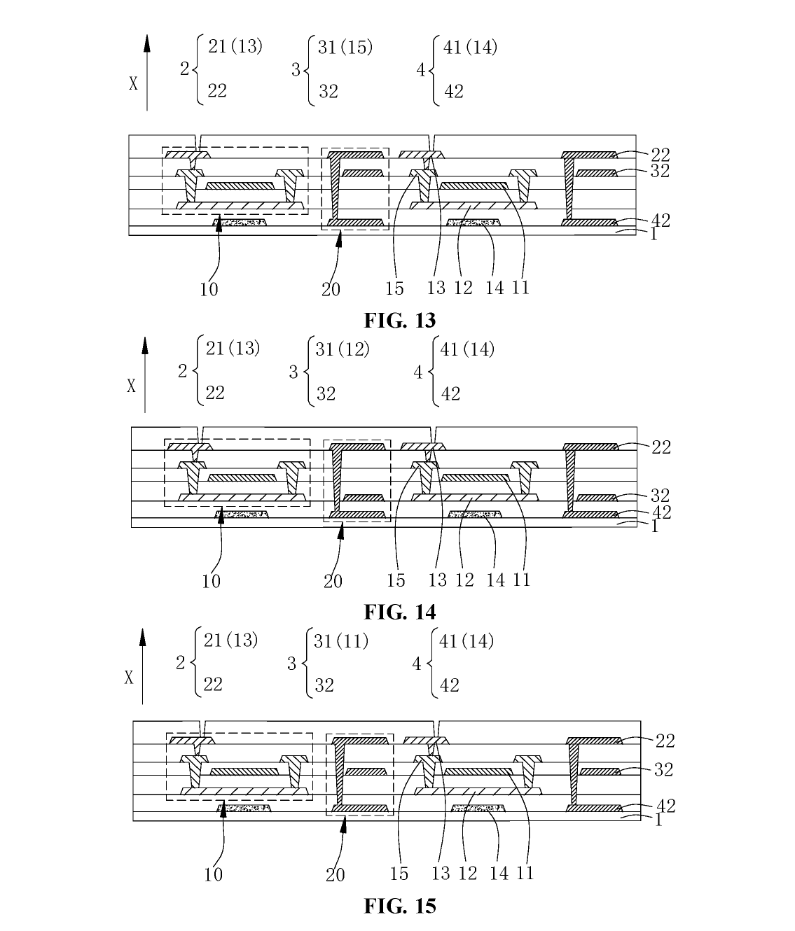

Exemplarily, referring to FIG. 13, the first conductive portion 21 serves as the first source-drain electrode 13, and the first electrode plate 22 and the first source-drain electrode 13 are manufactured in the same layer; the second conductive portion 31 serves as the second source-drain electrode 15, and the second electrode plate 32 and the second source-drain electrode 15 are manufactured in the same layer; and the third conductive portion 41 serves the second gate electrode 14, and the third electrode plate 42 and the second gate electrode 14 are manufactured in the same layer.

Referring to FIG. 14, in some embodiments, the first conductive portion 21 is the first source-drain electrode 13, the third conductive portion 41 is the second gate electrode 14, and the second conductive portion 31 is the active layer 12 or the first gate electrode 11.

Exemplarily, the first conductive portion 21 serves as the first source-drain electrode 13, and the first electrode plate 22 and the first source-drain electrode 13 are manufactured in the same layer; the second conductive portion 31 serves as the active layer 12, and the second electrode plate 32 and the active layer 12 are manufactured in the same layer; and the third conductive portion 41 serves as the second gate electrode 14, and the third electrode plate 42 and the second gate electrode 14 are manufactured in the same layer.

Exemplarily, referring to FIG. 15, the first conductive portion 21 serves as the first source-drain electrode 13, and the first electrode plate 22 and the first source-drain electrode 13 are manufactured in the same layer; the second conductive portion 31 serves as the first gate electrode 11, and the second electrode plate 32 and the first gate electrode 11 are manufactured in the same layer; and the third conductive portion 41 is the second gate electrode 14, and the third electrode plate 42 and the second gate electrode 14 are manufactured in the same layer.

When preparing the array base plate, the active layer 12 may be manufactured first, and then the first gate electrode 11 is manufactured. The first gate electrode 11 is used as a shielding layer to perform ion doping on the active layer 12, so as to improve the electrical properties of the source region 121 and the drain region 122 of the active layer 12, and form the channel region 123 on the active layer 12. When two electrode plates in the storage capacitor 20 are manufactured in the same layer as the active layer 12 and the first gate electrode 11, the electrode plate manufactured later may block the electrode plate previously manufactured for performing ion doping, so that the previously manufactured electrode plate cannot be ion-doped with the active layer 12. In some embodiments, ion doping is performed on the active layer 12 by providing a sacrificial layer replacing the first gate electrode 11, and then the sacrificial layer is removed to manufacture the first gate electrode 11. In some embodiments, when one of the first conductive portion 21, the second conductive portion 31, and the third conductive portion 41 serves as the active layer 12, the other two conductive portions form functional layers other than the first gate electrode 11 in the oxide transistor 10, thereby avoiding that any two electrode plates in the storage capacitor 20 are manufactured in the same layer as the active layer 12 and the first gate electrode 11, so that the previously manufactured electrode plates cannot be ion-doped. In some embodiments, when one of the first conductive portion 21, the second conductive portion 31, and the third conductive portion 41 serves as the first gate electrode 11, the two other conductive portions form functional layers other than the active layer 12 in the oxide transistor 10, thereby avoiding that any two electrode plates in the storage capacitor 20 are manufactured in the same layer as the active layer 12 and the first gate electrode 11, so that the previously manufactured electrode plates cannot be ion-doped.

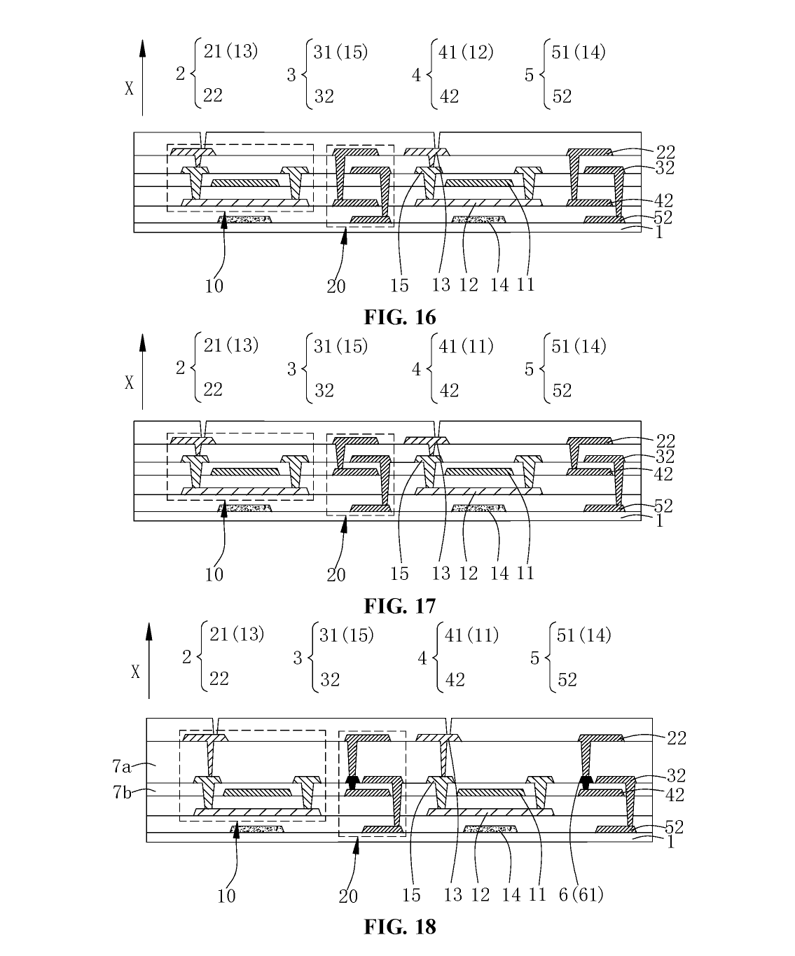

Referring to FIG. 16, in some embodiments, the array base plate further includes a fourth conductive layer 5, and the fourth conductive layer 5 is disposed at the side of the third conductive layer 4 close to the substrate 1; the fourth conductive layer 5 includes a fourth electrode plate 52, and the fourth electrode plate 52 is electrically connected to the second electrode plate 32; and the orthographic projection of the fourth electrode plate 52 on the substrate 1 at least partially overlaps the orthographic projection of the third electrode plate 42 on the substrate 1, and the first electrode plate 22, the second electrode plate 32, the third electrode plate 42, and the fourth electrode plate 52 form at least part of the storage capacitor 20.

During the manufacturing of the oxide transistor 10, the fourth conductive layer 5, the third conductive layer 4, the second conductive layer 3, and the first conductive layer 2 can be manufactured in sequence. The orthographic projection of the fourth electrode plate 52 on the substrate 1 at least partially overlaps the orthographic projection of the third electrode plate 42 on the substrate 1, so that a capacitor is formed between the first electrode plate 22 and the second electrode plate 32, a capacitor is formed between the second electrode plate 32 and the third electrode plate 42, and a capacitor is formed between the third electrode plate 42 and the fourth electrode plate 52. By disposing the first electrode plate 22, the second electrode plate 32, the third electrode plate 42, and the fourth electrode plate 52 to form the storage capacitor 20, the capacitance value of the storage capacitor 20 may be increased, the area of a single electrode plate may be reduced, and the area of the entire pixel circuit can be reduced.

The fourth electrode plate 52 is electrically connected to the second electrode plate 32, so that the fourth electrode plate 52 and the second electrode plate 32 have the same potential; and either the first electrode plate 22 or the fourth electrode plate 52 is electrically connected to other conductive structures to connected to the pixel circuit, thereby simplifying the design of the pixel circuit.

In some embodiments, the first electrode plate 22 and the third electrode plate 42 are electrically connected through a first via, the second electrode plate 32 and the fourth electrode plate 52 are electrically connected through a second via, and the first via and the second via are disposed on different sides of the storage capacitor 20, thereby avoiding electrical signal interference caused by the first via and the second via being close to each other. Optionally, the first via and the second via are disposed on the opposite sides of the storage capacitor 20 respectively.

In some embodiments, the third conductive layer 4 further includes a third conductive portion 41, and the third conductive portion 41 is spaced apart from the third electrode plate 42; the fourth conductive layer 5 further includes a fourth conductive portion 51, and the fourth conductive portion 51 is spaced apart from the fourth electrode plate 52; and the first conductive portion 21, the second conductive portion 31, the third conductive portion 41, and the fourth conductive portion 51 serve as four different functional portions of the oxide transistor 10 respectively.

The fourth conductive portion 51 is one of the first gate electrode 11, the second gate electrode 14, the active layer 12, the first source-drain electrode 13, and the second source-drain electrode 15 of the oxide transistor 10. When the conductive material is patterned to obtain the fourth conductive portion 51, the fourth electrode plate 52 is also manufactured, thereby simplifying the manufacturing step.

In some embodiments, the first conductive portion 21 serves as the first source-drain electrode 13, the second conductive portion 31 serves as the second source-drain electrode 15, the fourth conductive portion 51 serves as the second gate electrode 14, and the third conductive portion 41 serves as the active layer 12 or the first gate electrode 11.

Exemplarily, the first conductive portion 21 serves as the first source-drain electrode 13, and the first electrode plate 22 and the first source-drain electrode 13 are manufactured in the same layer; the second conductive portion 31 serves as the second source-drain electrode 15, and the second electrode plate 32 and the second source-drain electrode 15 are manufactured in the same layer; the third conductive portion 41 serves as the active layer 12, and the third electrode plate 42 and the active layer 12 are manufactured in the same layer; and the fourth conductive portion 51 serves as the second gate electrode 14, and the fourth electrode plate 52 and the second gate electrode 14 are manufactured in the same layer.

Exemplarily, referring to FIG. 17, the first conductive portion 21 is the first source-drain electrode 13, and the first electrode plate 22 and the first source-drain electrode 13 are manufactured in the same layer; the second conductive portion 31 is the second source-drain electrode 15, and the second electrode plate 32 and the second source-drain electrode 15 are manufactured in the same layer; the third conductive portion 41 is the first gate electrode 11, and the third electrode plate 42 and the first gate electrode 11 are manufactured in the same layer; and the fourth conductive portion 51 is the second gate electrode 14, and the fourth electrode plate 52 and the second gate electrode 14 are manufactured in the same layer.

Referring to FIG. 18, in some embodiments, a plurality of conductive layers include a fifth conductive layer 6, and the fifth conductive layer 6 includes a first connection portion 61; and the first conductive portion 21 is connected to the first connection portion 61 through a via, and the first connection portion 61 is connected to the third conductive portion 41 through a via.

The fifth conductive layer 6 may be any one of the plurality of conductive layers other than the first conductive layer 2, the second conductive layer 3, the third conductive layer 4, or the fourth conductive layer 5, and the fifth conductive layer 6 may also be one of the first conductive layer 2, the second conductive layer 3, the third conductive layer 4, and the fourth conductive layer 5.

The distance between the first conductive portion 21 and the third conductive portion 41 is too large, causing poor uniformity and high difficulty in forming the via connecting the first conductive portion 21 and the third conductive portion 41. By disposing the first connection portion 61, the first conductive portion 21 and the third conductive portion 41 can be electrically connected through the first connection portion 61, and the via connecting the first conductive portion 21 and the first connection portion 61 and the via connecting the first connection portion 61 and the third conductive portion 41 are individually formed, thereby reducing the depth of a single via, reducing the difficulty of forming the via, and improving the uniformity of the via.

In some embodiments, the fifth conductive layer 6 and the second conductive layer 3 are the same conductive layer, and the first connection portion 61, the second conductive portion 31, and the second electrode plate 32 are spaced apart from each other.

During patterning of the second conductive portion 31 and the second electrode plate 32, the first connection portion 61 is formed simultaneously, thereby simplifying the step of preparing the first connection portion 61.

In some embodiments, the array base plate further includes multiple insulation layers, the insulation layers are disposed between adjacent conductive layers, the multiple insulation layers include an organic insulation layer 7a, and the organic insulation layer 7a is disposed between the first conductive layer 2 and the second conductive layer 3.

Compared to the inorganic insulation layer 7b, the organic insulation layer 7a is easier to have a larger thickness. Since the first conductive layer 2 and the second conductive layer 3 are spaced apart from each other by the organic insulation layer 7a, the via connecting the first conductive layer 2 and the second conductive layer 3 has a relatively large depth. Based on this, it is difficult to form the via penetrating between the first conductive layer 2 and the third conductive layer 4. By disposing the first connection portion 61, the depth of a single via may be reduced, the difficulty of forming the via may be reduced, and the uniformity of the via is improved.

In some embodiments, the multiple insulation layers include at least one inorganic insulation layer 7b disposed between the second conductive layer 3 and the third conductive layer 4.

The manufacturing method of forming vias in the organic insulation layer 7a is different from that in the inorganic insulation layer 7b, so it is difficult to form the vias penetrating the organic insulation layer 7a and the inorganic insulation layer 7b. When at least one inorganic insulation layer 7b is disposed between the second conductive layer 3 and the third conductive layer 4, and the organic insulation layer 7a is disposed between the first conductive layer 2 and the second conductive layer 3, the first connection portion 61 is disposed to avoid forming the via penetrating the organic insulation layer 7a and the inorganic insulation layer 7b in one step.

In some embodiments, the multiple insulation layers include a second gate insulator (GI) layer, a first gate insulation layer, a first inter-layer dielectric (ILD) layer, and a first planarization (PLN) layer; and the second gate insulation layer is located between the second gate electrode 14 and the active layer 12, the first gate insulation layer is located between the active layer 12 and the first gate electrode 11, the first inter-layer dielectric layer is located between the first gate electrode 11 and the second source-drain electrode 15, and the first planarization layer is located between the second source-drain electrode 15 and the first source-drain electrode 13. The first planarization layer may serve as the organic insulation layer 7a. A gate buffer layer, the second gate insulation layer, the first gate insulation layer, and the first inter-layer dielectric layer may serve as inorganic insulation layers 7b. Optionally, the thickness of the second gate insulation layer along the first direction X ranges from 0.1 um to 0.15 um; the thickness of the first gate isolator layer along the first direction X ranges from 0.3 um to 0.55 um; the thickness of the first inter-layer dielectric layer along the first direction X ranges from 0.3 um to 0.5 um; and the thickness of the first planarization layer along the first direction X ranges from 1.5 μm to 2.2 μm.

The gate buffer layer, the second gate electrode 14, the second gate insulation layer, the active layer 12, the first gate insulation layer, the first gate electrode 11, the first inter-layer dielectric layer, the second source-drain electrode 15, the first planarization layer, and the first source-drain electrode 13 may be sequentially formed on the substrate 1.

Compared to an array base plate having both the oxide transistor 10 and the polysilicon transistor, the array base plate provided in the present application is an array base plate having only the oxide transistor 10, so the steps of preparing the polysilicon active layer 12 and the gate of the polysilicon transistor can be omitted, thereby improving the production efficiency.

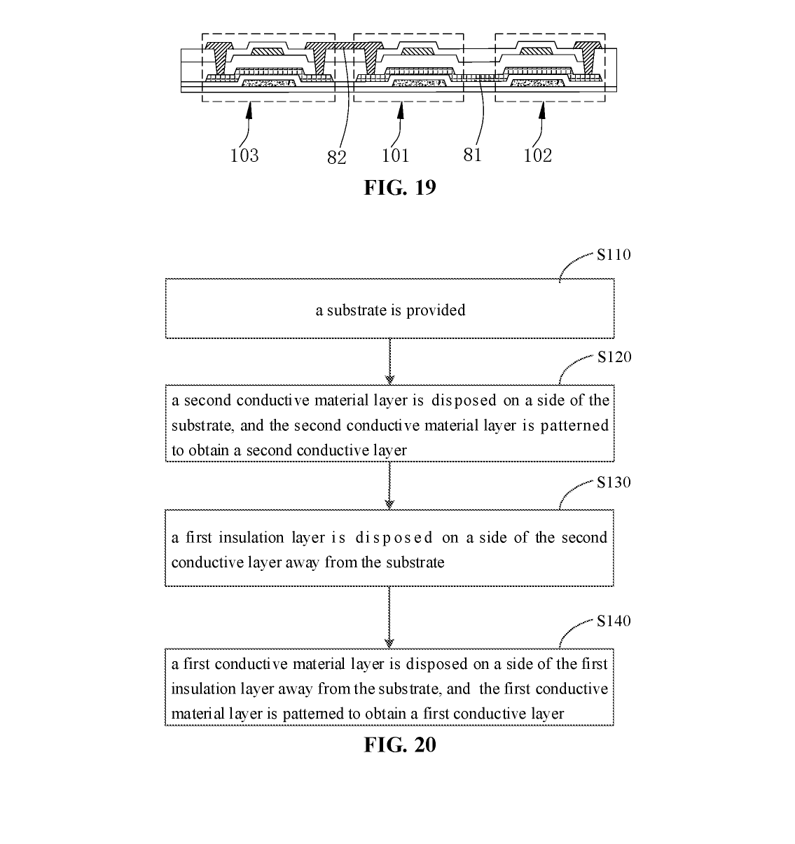

Referring to FIG. 19, in some embodiments, the pixel circuit includes a plurality of oxide transistors 10, the plurality of oxide transistors 10 include a first transistor 101 and a second transistor 102, and the active layer 12 of the first transistor 101 is connected to the active layer 12 of the second transistor 102.

The same functional portions of the plurality of oxide transistors 10 in the pixel circuit can be manufactured in the same layer, the active layer 12 of the first transistor 101 and the active layer 12 of the second transistor 102 are located in the same conductive layer in which a second connection portion 81 may be disposed, and the active layer 12 of the first transistor 101 is connected to the active layer 12 of the second transistor 102 through the second connection portion 81. The active layer 12 of the first transistor 101, the active layer 12 of the second transistor 102, and the second connection portion 81 are formed in the same conductive layer and are obtained by the same patterning step, eliminating the need to form vias on adjacent insulation layers to achieve electrical connection.

The plurality of oxide transistors 10 include a third transistor 103, the conductive layer including the second source-drain electrode 15 or the first source-drain electrode 13 has a third connection portion 82, the active region 121 of the third transistor 103 is connected to the third connection portion 82 through a via, and the active region 121 of the first transistor 101 is connected to the third connection portion 82 through a via.

The active layer 12 of the first transistor 101 and the active layer 12 of the third transistor 103 are located in the same conductive layer, and the conductive layer including the second source-drain electrode 15 or the first source-drain electrode 13 has a third connection portion 82, and the active layer 12 of the first transistor 101 and the active layer 12 of the third transistor 103 are connected through the third connection portion 82. The active layer 12 of the first transistor 101 is manufactured in the same layer as the active layer 12 of the third transistor 103, the second source-drain electrode 15 and the third connection portion 82 are prepared in the same layer, or the first source-drain electrode 13 and the third connection portion 82 are prepared in the same layer.

Compared to connect the active layers 12 of two transistors through the third connection portion 82, connecting the active layers 12 of two transistors through the second connection portion 81 eliminates the need for forming a via, so that the area of the second connection portion 81 can be smaller than the whole area of the third connection portion 82 and two vias, thereby reserving more space for distributing the electrode plates of the storage capacitor 20, which is conducive to the storage capacitor 20 adopting the solution including at least three electrode plates.

In another aspect, referring to FIG. 20, the present application further provides a method for manufacturing an array base plate, comprising: S110, S120, S130 and S140.

In S110, a substrate is taken;

In S120, a second conductive material layer is disposed on a side of the substrate, and the second conductive material layer is patterned to obtain a second conductive layer, wherein the second conductive layer comprises a second conductive portion and a second electrode plate spaced apart from each other;

In S130, a first insulation layer is disposed on a side of the second conductive layer away from the substrate;

In S140, a first conductive material layer is disposed on a side of the first insulation layer away from the substrate, and the first conductive material layer is patterned to obtain a first conductive layer, wherein the first conductive layer comprises a first conductive portion and a first electrode plate spaced apart from each other, an orthographic projection of the first electrode plate on the substrate at least partially overlaps an orthographic projection of the second electrode plate on the substrate, the first conductive portion and the second conductive portion serve as two different functional portions of an oxide transistor respectively, and the functional portions of the oxide transistor comprise a first gate electrode, an active layer, and a first source-drain electrode.

Referring to FIGS. 1-19, in the present application, the second conductive layer 3 is obtained by patterning the second conductive material layer, thereby omitting separately preparing the first conductive portion 21 and the first electrode plate 22; the first conductive material layer is patterned to obtain the first conductive layer 2, thereby eliminating the need to separately manufacture the second conductive portion 31 and the second electrode plate 32, and improving the manufacturing efficiency of the array base plate.

The method for manufacturing an array base plate provided in the embodiments of the present application can manufacture the array base plate provided in any one of the above embodiments, and therefore has the same technical effect, which will not be repeated here.

In some embodiments, prior to S120, the method further includes: S150 and S160.

In S150, a third conductive material layer is disposed at the side of the substrate, and the third conductive material layer is patterned to obtain a third conductive layer, wherein the third conductive layer comprises a third conductive portion and a third electrode plate spaced apart from each other.

In S160, a second insulation layer is disposed on a side of the third conductive material layer away from the substrate.

S140 includes: S141 and S142.

In S141, the first insulation layer and the second insulation layer are performed by a drilling process to obtain a first via exposing a portion of the third electrode plate.

In S142, a first conductive material layer is disposed on the side of the second insulation layer away from the substrate, and the first conductive material layer is patterned, wherein the third electrode plate and the first electrode plate are connected through the first via, the orthographic projection of the third electrode plate on the substrate at least partially overlaps the orthographic projection of the second electrode plate on the substrate, and the first conductive portion, the second conductive portion, and the third conductive portion are configured to serve as three different functional portions of the oxide transistor respectively,

wherein the functional portions of the oxide transistor further comprises a second gate electrode and a second source-drain electrode, the first gate electrode is located on the side of the active layer away from the substrate, the second gate electrode is located on the side of the active layer close to the substrate, the first source-drain electrode is disposed on the side of the second source-drain electrode away from the substrate, the first source-drain electrode is electrically connected to the second source-drain electrode, and the second source-drain electrode is electrically connected to the active layer.

Referring to FIGS. 1-19, the orthographic projection of the third electrode plate 42 on the substrate 1 at least partially overlaps the orthographic projection of the second electrode plate 32 on the substrate 1, so that a capacitor is formed between the first electrode plate 22 and the second electrode plate 32, and a capacitor is formed between the second electrode plate 32 and the third electrode plate 42. The first electrode plate 22, the second electrode plate 32, and the third electrode plate 42 is disposed to form the storage capacitor 20, which can increase the capacitance value of the storage capacitor 20 and reduce the area of a single electrode plate. When the array base plate is applied to a display panel, the pixel circuits control the light-emission units in one-to-one correspondence, and the area of a single electrode plate is reduced, so the area of the entire pixel circuit can be reduced, and the distance between adjacent light-emission units can be reduced.

The third electrode plate 42 is electrically connected to the first electrode plate 22, so that the third electrode plate 42 and the first electrode plate 22 have the same potential, and either the first electrode plate 22 or the third electrode plate 42 is electrically connected to other conductive structures to connect the pixel circuit, thereby simplifying the design of the pixel circuit.

In some embodiments, before S150, the method further includes: S170 and S180.

In S170, a fourth conductive material layer is disposed at the side of the substrate, and the fourth conductive material layer is patterned to obtain a fourth conductive layer, wherein the fourth conductive layer comprises a fourth conductive portion and a fourth electrode plate spaced apart from each other.

In S180, a third insulation layer is disposed on the side of the fourth conductive material layer away from the substrate.

S120 includes: S121 and S123.

In S121, the second insulation layer and the third insulation layer are performed by the drilling process to obtain a second via exposing a portion of the fourth electrode plate.

In S123, a second conductive material layer is disposed on the side of the second insulation layer away from the substrate 1, the second conductive material layer is patterned, wherein the fourth electrode plate and the second electrode plate are connected through a second via, the orthographic projection of the fourth electrode plate on the substrate at least partially overlaps the orthographic projection of the third electrode plate on the substrate, and the first conductive portion, the second conductive portion, the third conductive portion, and the fourth conductive portion are configured to serve as four different functional portions of the oxide transistor respectively.

Referring to FIGS. 1-19, the orthographic projection of the fourth electrode plate 52 on the substrate 1 at least partially overlaps the orthographic projection of the third electrode plate 42 on the substrate 1, so that a capacitor is formed between the first electrode plate 22 and the second electrode plate 32, a capacitor is formed between the second electrode plate 32 and the third electrode plate 42, and a capacitor is formed between the third electrode plate 42 and the fourth electrode plate 52. By disposing the first electrode plate 22, the second electrode plate 32, the third electrode plate 42, and the fourth electrode plate 52 to form the storage capacitor 20, the capacitance value of the storage capacitor 20 may be increased, the area of a single electrode plate may be reduced, and the area of the entire pixel circuit can be reduced.

The fourth electrode plate 52 is electrically connected to the second electrode plate 32, so that the fourth electrode plate 52 and the second electrode plate 32 have the same potential; and either the first electrode plate 22 or the fourth electrode plate 52 is electrically connected to other conductive structures to connected to the pixel circuit, thereby simplifying the design of the pixel circuit.

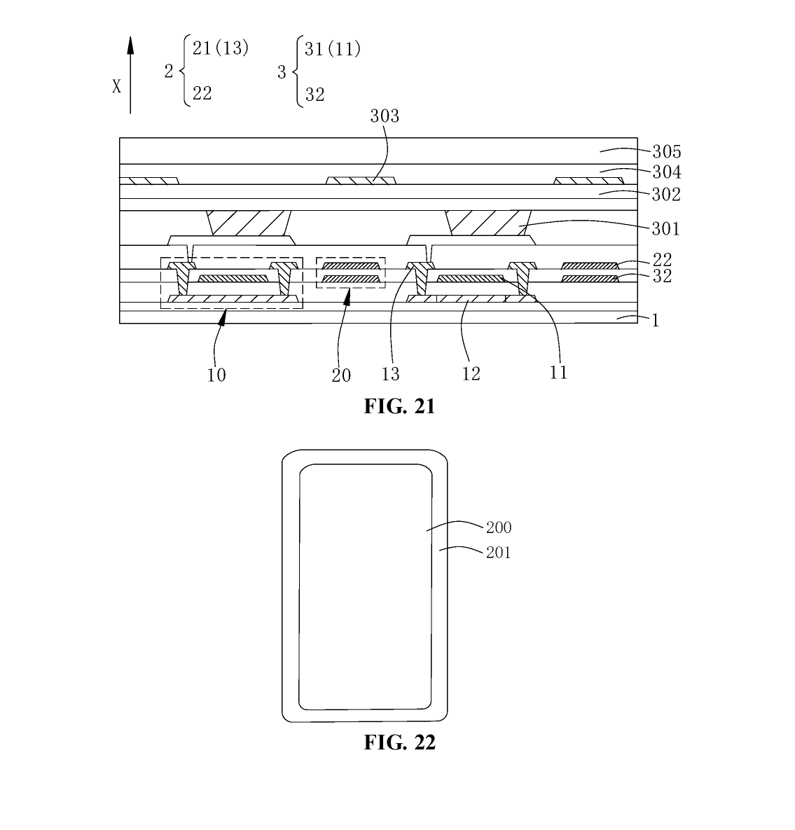

In another aspect, referring to FIG. 21, the present application further provides a display panel. The display panel includes the array base plate provided in any one of the above embodiments, or the array base plate manufactured by the method for manufacturing an array base plate provided in any one of the above embodiments, and therefore has the same technical effect, which will not be repeated here.

The display panel further includes a light-emission device layer disposed on one side of the array base plate, and the light-emission device layer includes a plurality of light-emission units 301. The display panel may further include an encapsulation layer 302, a touch layer 303, an adhesive layer 304, and a cover plate 305; the encapsulation layer 302 is configured to encapsulate the light-emission unit 301 to reduce the entry of external water and oxygen into the light-emission unit 301; and the touch layer 303 is disposed on the side of the light-emission device layer away from the substrate 1, and the touch layer 303 may achieve a touch function. The cover plate 305 is disposed at the side of the touch layer 303 away from the substrate 1. The cover plate 305 can protect the touch layer 303 and the light-emission device layer, and reduce or avoid external force from damaging the touch layer 303 and the light-emission device layer. The adhesive layer 304 is configured to adhere the touch layer 303 and the cover plate 305.

In another aspect, referring to FIG. 22, the present application further provides a display apparatus. The display apparatus includes the display panel 200 provided in any one of the above embodiments, and thus has the same technical effect, which will not be repeated here.

The display apparatus provided in the present application may further include a housing 201 supporting the display panel 200. The display apparatus provided in the embodiments of the present application may be applied to a mobile phone, or may be any electronic product having a display function, the electronic product includes but not limited to the following categories: televisions, notebook computers, desktop displays, tablet computers, digital cameras, smart bracelets, smart glasses, vehicle displays, medical devices, industrial control devices, touch interactive terminals, and the like, and the embodiments of the present application are not particularly limited thereto.

In addition, the term “and/or” used herein refers to only an association relationship for describing associated objects, which includes three types of relationships. For example, “A and/or B” may represent three possible cases including “A existing alone”, “A and B existing simultaneously”, and “B existing alone”. In addition, the character “/” herein generally indicates that the associated objects have an “or” relationship. It should be understood that, in the embodiments of the present application, “B corresponding to A” represents that B is associated with A, and B may be determined according to A. However, it should further be understood that B being determined according to A does not merely mean B being determined according to A, but also means B may further being determined according to A and/or other information.

The above are only specific implementations of the present application, but the protection scope of the present application is not limited to this, and any person skilled in the art can easily think of various equivalent modifications or replacements within the technical scope disclosed in the present application, and these modifications or replacements should all be covered within the scope of protection in the present application. Therefore, the protection scope of the present application should be subject to the protection scope of the claims.

What is claimed is:

1. An array base plate, comprising a pixel circuit comprising at least one oxide transistor and at least one storage capacitor, the array base plate comprising a substrate and a plurality of conductive layers, the plurality of conductive layers being sequentially arranged at a side of the substrate; the plurality of conductive layers comprising:
a first conductive layer, disposed at the side of the substrate, the first conductive layer comprising a first conductive portion and a first electrode plate that are spaced apart from each other;
a second conductive layer, disposed between the first conductive layer and the substrate, the second conductive layer comprising a second conductive portion and a second electrode plate that are spaced apart from each other,
wherein an orthographic projection of the first electrode plate on the substrate and an orthographic projection of the second electrode plate on the substrate at least partially overlap, the first electrode plate and the second electrode plate form at least part of the storage capacitor, the first conductive portion and the second conductive portion form two different functional portions of the oxide transistor respectively, and the functional portions of the oxide transistor comprise a first gate electrode, an active layer, and a first source-drain electrode.

2. The array base plate according to claim 1, wherein the functional portions of the oxide transistor further comprise a second gate electrode, the first gate electrode is located at a side of the active layer away from the substrate, the second gate electrode is located at a side of the active layer close to the substrate, an orthographic projection of the first gate electrode on the substrate partially overlaps an orthographic projection of the active layer on the substrate, and an orthographic projection of the second gate electrode on the substrate partially overlaps the orthographic projection of the active layer on the substrate.

3. The array base plate according to claim 1, wherein the functional portions of the oxide transistor further comprise a second source-drain electrode, the first source-drain electrode is disposed at a side of the second source-drain electrode away from the substrate, the first source-drain electrode is electrically connected to the second source-drain electrode, and the second source-drain electrode is electrically connected to the active layer.

4. The array base plate according to claim 1, wherein the functional portions of the oxide transistor further comprise a second gate electrode, the first gate electrode is located at a side of the active layer away from the substrate, the second gate electrode is located at a side of the active layer close to the substrate, an orthographic projection of the first gate electrode on the substrate partially overlaps an orthographic projection of the active layer on the substrate, an orthographic projection of the second gate electrode on the substrate partially overlaps the orthographic projection of the active layer on the substrate,
the functional portions of the oxide transistor further comprise a second source-drain electrode, the first source-drain electrode is disposed at a side of the second source-drain electrode away from the substrate, the first source-drain electrode is electrically connected to the second source-drain electrode, and the second source-drain electrode is electrically connected to the active layer.

5. The array base plate according to claim 4, further comprising:
a third conductive layer disposed at a side of the second conductive layer close to the substrate, wherein
the third conductive layer comprising a third electrode plate,
the third electrode plate is electrically connected to the first electrode plate,
an orthographic projection of the third electrode plate on the substrate and an orthographic projection of the second electrode plate on the substrate at least partially overlap, and
the first electrode plate, the second electrode plate and the third electrode plate form at least part of the storage capacitor.

6. The array base plate according to claim 5, wherein the third conductive layer further comprises a third conductive portion spaced apart from the third electrode plate, and the first conductive portion, the second conductive portion and the third conductive portion form three different functional portions of the oxide transistor respectively.

7. The array base plate according to claim 6, wherein the first conductive portion is the second source-drain electrode, the third conductive portion is the second gate electrode, and the second conductive portion is the active layer or the first gate electrode.

8. The array base plate according to claim 6, wherein the first conductive portion is the first source-drain electrode, the second conductive portion is the second source-drain electrode, and the third conductive portion is any one of the first gate electrode, the active layer and the second gate electrode.

9. The array base plate according to claim 6, wherein the first conductive portion is the first source-drain electrode, the third conductive portion is the second gate electrode, and the second conductive portion is the active layer or the first gate electrode.

10. The array base plate according to claim 5, further comprising:
a fourth conductive layer disposed at a side of the third conductive layer close to the substrate, wherein
the fourth conductive layer comprises a fourth electrode plate,
the fourth electrode plate is electrically connected to the second electrode plate,
an orthographic projection of the fourth electrode plate on the substrate and an orthographic projection of the third electrode plate on the substrate at least partially overlap, and
the first electrode plate, the second electrode plate, the third electrode plate and the fourth electrode plate form at least part of the storage capacitor.

11. The array base plate according to claim 10, wherein the third conductive layer further comprises a third conductive portion spaced apart from the third electrode plate,
the fourth conductive layer further comprises a fourth conductive portion spaced apart from the fourth electrode plate, and
the first conductive portion, the second conductive portion, the third conductive portion and the fourth conductive portion form four different functional portions of the oxide transistor respectively.

12. The array base plate according to claim 11, wherein the first conductive portion is the first source-drain electrode, the second conductive portion is the second source-drain electrode, the fourth conductive portion is the second gate electrode, and the third conductive portion is the active layer or the first gate electrode.

13. The array base plate according to claim 8, wherein the plurality of conductive layers comprise a fifth conductive layer, the fifth conductive layer comprises a first connection portion, the first conductive portion is connected to the first connection portion via a via, and the first connection portion is connected to the third conductive portion via a via.

14. The array base plate according to claim 13, wherein the fifth conductive layer and the second conductive layer are the same conductive layer, and the first connection portion, the second conductive portion and the second electrode plate are spaced apart from each other.

15. The array base plate according to claim 14, further comprising a plurality of insulation layers disposed between adjacent ones of the conductive layers, the plurality of insulation layers comprise an organic insulation layer, and the organic insulation layer is disposed between the first conductive layer and the second conductive layer.

16. The array base plate according to claim 15, wherein the plurality of insulation layers comprise at least one inorganic insulation layer, disposed between the second conductive layer and the third conductive layer.

17. The array base plate according to claim 1, further comprising a plurality of insulation layers disposed between adjacent ones of the conductive layers, and at least one of the insulation layers is disposed between the first electrode plate and the second electrode plate.

18. The array base plate according to claim 1, wherein the pixel circuit comprises a plurality of oxide transistors comprising a first transistor and a second transistor, and the active layer of the first transistor is connected to the active layer of the second transistor.

19. A method for manufacturing an array base plate, comprising:
providing a substrate;
disposing a second conductive material layer at a side of the substrate, and patterning the second conductive material layer to obtain a second conductive layer, that comprise a second conductive portion and a second electrode plate spaced apart from each other;
disposing a first insulation layer at a side of the second conductive layer away from the substrate;
disposing a first conductive material layer at a side of the first insulation layer away from the substrate, and patterning the first conductive material layer to obtain a first conductive layer that comprises a first conductive portion and a first electrode plate spaced apart from each other, wherein an orthographic projection of the first electrode plate on the substrate and an orthographic projection of the second electrode plate on the substrate at least partially overlap, the first conductive portion and the second conductive portion form two different functional portions of an oxide transistor respectively, and the functional portions of the oxide transistor comprise a first gate electrode, an active layer, and a first source-drain electrode.

20. A display panel, comprising an array base plate comprising a pixel circuit comprising at least one oxide transistor and at least one storage capacitor, the array base plate comprising a substrate and a plurality of conductive layers, the plurality of conductive layers being sequentially arranged at a side of the substrate; the plurality of conductive layers comprising:
a first conductive layer, disposed at the side of the substrate, the first conductive layer comprising a first conductive portion and a first electrode plate that are spaced apart from each other;
a second conductive layer, disposed between the first conductive layer and the substrate, the second conductive layer comprising a second conductive portion and a second electrode plate that are spaced apart from each other,
wherein an orthographic projection of the first electrode plate on the substrate and an orthographic projection of the second electrode plate on the substrate at least partially overlap, the first electrode plate and the second electrode plate form at least part of the storage capacitor, the first conductive portion and the second conductive portion form two different functional portions of the oxide transistor respectively, and the functional portions of the oxide transistor comprise a first gate electrode, an active layer, and a first source-drain electrode, or
the array base plate manufactured by a method for manufacturing the array base plate, the method comprising:
providing a substrate;
disposing a second conductive material layer at a side of the substrate, and patterning the second conductive material layer to obtain a second conductive layer, that comprise a second conductive portion and a second electrode plate spaced apart from each other;
disposing a first insulation layer at a side of the second conductive layer away from the substrate;
disposing a first conductive material layer at a side of the first insulation layer away from the substrate, and patterning the first conductive material layer to obtain a first conductive layer that comprises a first conductive portion and a first electrode plate spaced apart from each other, wherein an orthographic projection of the first electrode plate on the substrate and an orthographic projection of the second electrode plate on the substrate at least partially overlap, the first conductive portion and the second conductive portion form two different functional portions of an oxide transistor respectively, and the functional portions of the oxide transistor comprise a first gate electrode, an active layer, and a first source-drain electrode.
